(19) United States
(12) Patent Application Publication
(10) Pub. No.: US 2026/0368375 A1
(43) Pub. Date: Nov. 19, 2026

(54) CAD MODEL ANALYSIS

(71) Applicant: Palantir Technologies Inc., Denver, CO (US)

(72) Inventors: Henry Stoke, London (GB); Krishan Bhalla, London (GB)

(21) Appl. No.: 19/232,638

(22) Filed: Jun. 9, 2025

Related U.S. Application Data
(60) Provisional application No. 63/807,088, filed on May 16, 2025.

(51) Int. Cl. G06F 30/12; G06F 30/20

(52) U.S. Cl. CPC G06F 30/12; G06F 30/20

(57) ABSTRACT

A CAD analysis system may access a CAD model and determine a technical requirement to be applied to the CAD model, the technical requirement including a plurality of geometric computations configured to identify potential design, manufacturing, compliance, functional, or optimization issues with the CAD model. The system may perform a first geometric computation on the CAD model and then a second geometric computation on the CAD model, the second geometric computation based at least in part on results of the first geometric computation. The system may identify one or more potential issues in the CAD model based at least in part on the results of the second or subsequent geometric computations. The system may display, via a user interface, the identified potential issues in the CAD model.

### TECHNICAL FIELD

The present disclosure relates to systems and techniques for data integration, analysis, and visualization.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Technical requirements for a CAD model can be determined by geometric operations. The results can be displayed to the user for review. Various techniques have been developed to lower computational costs associated with determining potential issues with a CAD model.

### SUMMARY

The systems, methods, and devices described herein each have several aspects, no single one of which is solely responsible for its desirable attributes. Without limiting the scope of this disclosure, several non-limiting features will be described briefly.

A CAD model is a digital representation of a 3D object. CAD software allows the user to create a new object or to modify and design innovative improvements to the object. However, many objects designed in a CAD software must comply with certain safety and regulation rules. Current techniques require a user to review each component of the object to ensure they align with their respective safety requirements. Moreover, the reviewed safety rules are not savable or transferable to future modifications to the object, therefore the user would have to restart the review process for each modification. Additionally, current CAD software does not support integration of model design with technical requirements created dynamically by individual businesses or for specialized needs.

The present disclosure implements systems and methods that can advantageously overcome the technical challenges mentioned above, among other technical challenges. The present disclosure further includes various processes, functionality, and interactive graphical user interfaces (hereinafter a “GUI”) related to the system. The system can advantageously provide an efficient and user-friendly process for quickly creating technical requirements designed to validate model compliance with specific engineering/safety requirements, identifying potential issues in the CAD model according to the technical requirements (e.g., highlighting portions that do not comply with a technical requirement), and displaying the potential issues to the user for review, as described herein. For example, according to various implementations, the system, (and related processes, functionality, and interactive GUIs), can advantageously create technical requirements, which may include a series of sequential geometric computations, that can be applied to components of a CAD model to identify potential issues with the CAD model (or, more specifically, to a real world physical implementation of the CAD model) and highlighting components (or portions of components) that do not meet the specified rules. The system can then display the components for the user to review.

Accordingly, in various embodiments, large amounts of data are automatically and dynamically calculated interactively in response to user inputs, and the calculated data is efficiently and compactly presented to a user by the system. Thus, in some embodiments, the user interfaces described herein are more efficient compared to previous user interfaces in which data is not dynamically updated and compactly and efficiently presented to the user in response to interactive inputs.

Further, as described herein, the system may be configured and/or designed to generate user interface data useable for rendering the various interactive user interfaces described. The user interface data may be used by the system, and/or another computer system, device, and/or software program (for example, a browser program), to render the interactive user interfaces. The interactive user interfaces may be displayed on, for example, electronic displays (including, for example, touch-enabled displays).

Additionally, it has been noted that design of computer user interfaces that are useable and easily learned by humans is a non-trivial problem for software developers. The various embodiments of interactive and dynamic user interfaces of the present disclosure are the result of significant research, development, improvement, iteration, and testing. This non-trivial development has resulted in the user interfaces described herein which may provide significant cognitive and ergonomic efficiencies and advantages over previous systems. The interactive and dynamic user interfaces include improved human-computer interactions that may provide reduced mental workloads, improved decision-making, reduced work stress, and/or the like, for a user. For example, user interaction with the interactive user interfaces described herein may provide an optimized display of time-varying report-related information and may enable a user to more quickly access, navigate, assess, and digest such information than previous systems.

In some embodiments, data may be presented in graphical representations, such as visual representations, such as charts and graphs, where appropriate, to allow the user to comfortably review the large amount of data and to take advantage of humans' particularly strong pattern recognition abilities related to visual stimuli. In some embodiments, the system may present aggregate quantities, such as totals, counts, and averages. The system may also utilize the information to interpolate or extrapolate, e.g. forecast, future developments.

Further, the interactive and dynamic user interfaces described herein are enabled by innovations in efficient interactions between the user interfaces and underlying systems and components. For example, disclosed herein are improved methods of receiving user inputs, translation and delivery of those inputs to various system components, automatic and dynamic execution of complex processes in response to the input delivery, automatic interaction among various components and processes of the system, and automatic and dynamic updating of the user interfaces. The interactions and presentation of data via the interactive user interfaces described herein may accordingly provide cognitive and ergonomic efficiencies and advantages over previous systems.

Various embodiments of the present disclosure provide improvements to various technologies and technological fields. For example, as described above, existing data storage and processing technology (including, e.g., in memory databases) is limited in various ways (e.g., manual data review is slow, costly, and less detailed; data is too voluminous; etc.), and various embodiments of the disclosure provide significant improvements over such technology. Additionally, various embodiments of the present disclosure are inextricably tied to computer technology. In particular, various embodiments rely on detection of user inputs via graphical user interfaces, calculation of updates to displayed electronic data based on those user inputs, automatic processing of related electronic data, and presentation of the updates to displayed images via interactive graphical user interfaces. Such features and others (e.g., processing and analysis of large amounts of electronic data) are intimately tied to, and enabled by, computer technology, and would not exist except for computer technology. For example, the interactions with displayed data described below in reference to various embodiments cannot reasonably be performed by humans alone, without the computer technology upon which they are implemented. Further, the implementation of the various embodiments of the present disclosure via computer technology enables many of the advantages described herein, including more efficient interaction with, and presentation of, various types of electronic data.

Certain embodiments of a CAD model review system environment discussed herein may include any combination of the technical features below:
The ability to scan large PDF (or other format) business rules, engineering requirements, and/or other project files to auto translate into technical requirements including one or more geometric computations.
Geometric computations may include functions such as: check no collisions, get component centroid, collide mesh with scene, get mesh faces, get principal axes, raycast to components, get closest point, add direction to point, get perpendicular axes, get measurement, create sphere, get opposite direction, get screen grab, get cross section image, create cylinder, get limits along axis, numeric comparison, numeric arithmetic, component has color, boolean comparison, boolean not, get cross section, compile polygon to shapes, create polygon literal, find free orientation, add directions by weight, get measurement endpoint, get polygon centroid, and/or the like.
The geometric computations may be performed with references to any component, or combination of components in a CAD model. Additionally, certain geometric computations may be performed with reference to a: scene, component, sphere mesh, cylinder mesh, mesh, mesh face polygon, mesh cross section polygon, literal polygon, polygon, point, direction, image, measurement, color, double, integer, string, boolean, minimal collision orientation, and/or the like.
The ability to import CAD files into a CAD analysis system
Software can give more deterministic measurements than current systems
   This system can combine and sequence through rules that can build on top of each other
   Offers structured information about designs such as finding all bolts in a model and their distance from nuts etc.
The ability to perform a sequence of geometric computations to achieve a specific business rule
LLM Models can be asked narrative prompts about the model after given sufficient information
Some geometric computations are standard computations, while other are more complex and created as-needed for each specific requirement
CAD Model dynamically visually displays results of the sequence of geometric computations
The ability to import a CAD model into a data management system to preprocess the results of the applied technical requirements to provide the engineer with a structured view of each determined issue
   User can save results of technical requirement analysis and the data management system can display all alerts
   Alternatively, the data management system may instantly update highlighted issues as the user works on the model
   User can choose to ignore highlighted issues, send the model back to designer, and/or escalate the issue to another user
   The ability to manipulate what issues the data management system will show you
      If changes were only made to one section of the design, only shows you issues relating to that area
      Will not show you issues it previously flagged that you chose to ignore
      Can configure technical requirements to only alert in specified circumstances
   Storing the CAD model according to an ontology used by the data management system allows interactivity, as opposed to merely display
The ability to propose fixes to comply with technical requirements

Additional embodiments of the disclosure are described below in reference to the appended claims, which may serve as an additional summary of the disclosure.

In various embodiments, systems and/or computer systems are disclosed that comprise a computer readable storage medium having program instructions embodied therewith, and one or more processors configured to execute the program instructions to cause the one or more processors to perform operations comprising one or more aspects of the above-and/or below-described embodiments (including one or more aspects of the appended claims).

In various embodiments, computer-implemented methods are disclosed in which, by one or more processors executing program instructions, one or more aspects of the above-and/or below-described embodiments (including one or more aspects of the appended claims) are implemented and/or performed.

In various embodiments, computer program products comprising a computer readable storage medium are disclosed, wherein the computer readable storage medium has program instructions embodied therewith, the program instructions executable by one or more processors to cause the one or more processors to perform operations comprising one or more aspects of the above-and/or below-described embodiments (including one or more aspects of the appended claims).

### BRIEF DESCRIPTION OF THE DRAWINGS

FIG. 1A is a block diagram illustrating a CAD model review system, according to some embodiments of the present disclosure.

FIG. 1B is a block diagram illustrating example components of a data management system, according to some embodiments of the present disclosure.

FIG. 1C is a block diagram illustrating an example sequential CAD model data transformation.

FIG. 2A illustrates an example first geometric computation in a sequential data transformation for a CAD model.

FIG. 2B illustrates an example display of a CAD model following a first geometric computation.

FIG. 3 illustrates an example second geometric computation in a sequential data transformation for a CAD model.

FIG. 4A illustrates an example third and fourth geometric computation in a sequential data transformation for a CAD model.

FIG. 4B illustrates an example display of a CAD model following a series of geometric computations.

FIG. 5 illustrates an example user interface for reviewing a CAD model.

FIG. 6 illustrates example geometric computations for use in a sequential data transformation.

FIG. 7 is a flowchart of one embodiment of a process for identifying and displaying potential issues in a CAD model.

FIG. 8 is a block diagram illustrating a computer system with which certain methods discussed herein may be implemented, according to some embodiments of the present disclosure.

### DETAILED DESCRIPTION

Although certain preferred implementations, embodiments, and examples are discussed below, the inventive subject matter extends beyond the specifically disclosed implementations to other alternative implementations and/or uses and to modifications and equivalents thereof. Thus, the scope of the claims appended hereto is not limited by any of the particular implementations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain implementations; however, the order of description should not be construed to imply that these operations are order dependent. Additionally, the structures, systems, and/or devices described herein may be embodied as integrated components or as separate components. For purposes of comparing various implementations, certain aspects and advantages of these implementations are described. Not necessarily all such aspects or advantages are achieved by any particular implementation. Thus, for example, various implementations may be carried out in a manner that achieves or optimizes one advantage or group of advantages as taught herein without necessarily achieving other aspects or advantages as may also be taught or suggested herein.

### Overview

In some aspects and/or embodiments, systems, methods, and computer program products described herein include and/or implement the ability to create, store, and apply technical requirements that can be used to automate the engineering requirement review process for newly designed and/or modified CAD Models to validate the CAD model for compliance with safety requirements. The user may utilize specific geometric computations based on the specific engineering requirement they are reviewing. For example, a user may want to determine if struts experience a collision in the region of its centroid. In such an example, the user can create a technical requirement by utilizing a series of geometric computations that build off of the previous geometric computation. For example, geometric computations can be utilized that find the centroid of the strut, finds the direction of each strut (based on principle moments of inertia), creates a cylinder at the center of each strut (based on the centroid and the direction), and highlights the strut depending on whether there is a collision detected at the center of the strut (based on the cylinder created at the center of the strut). The user may then upload the result CAD model to a data management system to review the detected collisions.

To facilitate an understanding of the systems and methods discussed herein, a number of terms are described below. The terms described below, as well as other terms used herein, should be construed to include the provided descriptions, the ordinary and customary meaning of the terms, and/or any other implied meaning for the respective terms. Thus, the descriptions below do not limit the meaning of these terms but only provide exemplary descriptions.
Ontology: Stored information that provides a data model for storage of data in one or more databases. For example, the stored data may comprise definitions for data object types and respective associated property types. An ontology may also include respective link types/definitions associated with data object types, which may include indications of how data object types may be related to one another. An ontology may also include respective actions associated with data object types. The actions associated with data object types may include, e.g., defined changes to values of properties based on various inputs. An ontology may also include respective functions, or indications of associated functions, associated with data object types, which functions, e.g., may be executed when a data object of the associated type is accessed. An ontology may constitute a way to represent things in the world. An ontology may be used by an organization to model a view on what objects exist in the world, what their properties are, and how they are related to each other. An ontology may be user-defined, computer-defined, or some combination of the two. An ontology may include hierarchical relationships among data object types.
Data Store: Any computer readable storage medium and/or device (or collection of data storage mediums and/or devices). Examples of data stores include, but are not limited to, optical disks (e.g., CD-ROM, DVD-ROM, etc.), magnetic disks (e.g., hard disks, floppy disks, etc.), memory circuits (e.g., solid state drives, random-access memory (RAM), etc.), and/or the like. Another example of a data store is a hosted storage environment that includes a collection of physical data storage devices that may be remotely accessible and may be rapidly provisioned as needed (commonly referred to as “cloud” storage).
Database: Any data structure (and/or combinations of multiple data structures) for storing and/or organizing data, including, but not limited to, relational databases (e.g., Oracle databases, PostgreSQL databases, etc.), non-relational databases (e.g., NoSQL databases, etc.), in-memory databases, spreadsheets, as comma separated values (CSV) files, eXtendible markup language (XML) files, TeXT (TXT) files, flat files, spreadsheet files, and/or any other widely used or proprietary format for data storage. Databases are typically stored in one or more data stores. Accordingly, each database referred to herein (e.g., in the description herein and/or the figures of the present application) is to be understood as being stored in one or more data stores.
Data Object or Object: A data container for information representing specific things in the world that have a number of definable properties. For example, a data object can represent an entity such as a person, a place, an organization, a market instrument, or other noun. A data object can represent an event that happens at a point in time or for a duration. A data object can represent a document or other unstructured data source such as an e-mail message, a news report, or a written paper or article. Each data object may be associated with a unique identifier that uniquely identifies the data object. The object's attributes (e.g. metadata about the object) may be represented in one or more properties.
Object Type: Type of a data object (e.g., Person, Event, or Document). Object types may be defined by an ontology and may be modified or updated to include additional object types. An object definition (e.g., in an ontology) may include how the object is related to other objects, such as being a sub-object type of another object type (e.g. an agent may be a sub-object type of a person object type), and the properties the object type may have.
Properties: Attributes of a data object that represent individual data items. At a minimum, each property of a data object has a property type and a value or values.
Property Type: The type of data a property is, such as a string, an integer, or a double. Property types may include complex property types, such as a series data values associated with timed ticks (e.g. a time series), etc.
Property Value: The value associated with a property, which is of the type indicated in the property type associated with the property. A property may have multiple values.
Link: A connection between two data objects, based on, for example, a relationship, an event, and/or matching properties. Links may be directional, such as one representing a payment from person A to B, or bidirectional.
Link Set: Set of multiple links that are shared between two or more data objects.
CAD Model: A digital representation of a physical object created using computer-aided design (CAD) software. CAD Models offer precise measurements and accurately simulate real world properties of the physical object. CAD Models can be created, for example, to design a physical object before utilizing manufacturing resources to ensure the physical object is adequately designed. CAD Models can also simulate changes to the physical object, such as during manufacture or use of the object. For example, CAD Models can simulate the various steps of the manufacture of the object as components are added.
Component: An individual part of a CAD model. For example, if a CAD model is created to illustrate the assembled design of a box made of six metal plates, each of the six metal plates would be components of the model. Each component in a CAD model contains physical properties such as physical measurements, physical durability and strain, etc. A CAD model may also include a count of each component within the CAD model. Components can be measured, counted, and altered as part of the design process in the CAD software.
Technical requirement: A rule for the design of the CAD model determined by the user to ensure that the fabricated product based on the CAD model meets necessary safety, utility, and/or any other requirement set by the user. A technical requirement can be set to test a component of the CAD model, relationships between components, the entirety of the CAD model, and/or any other aspect of the CAD model. Technical requirements are generally important to the design of the CAD model but are not inherently determinable with current CAD systems. Thus, technical requirements are commonly hand reviewed by the user for each component/model affected by the technical requirement.
Geometric Computation: Accessing component properties (such as dimensions, positions, orientations, or other physical attributes) and applying geometric, arithmetic, or other logical operations to analyze, manipulate, or derive new information about the components or the overall CAD model. Geometric computations can involve measuring physical properties of the CAD model, such as distance to a center point, collision detection, and/or other various measurements of a CAD model. A technical requirement may include multiple geometric computations that are applied to a CAD model sequentially, where the output of one technical requirement is used by subsequent technical requirements(s) to determine whether the CAD model satisfies the technical requirement. For example, a first geometric computation can be applied to find the center point of each instance of a particular component in a CAD model. A second geometric computation can then be applied, based on respective center points of the components, to find orientations of the components. Sequentially applying geometric computations allows for the user to apply more robust computations to the CAD model without sacrificing efficiency of the system.

### Example System and Related Computing Environment

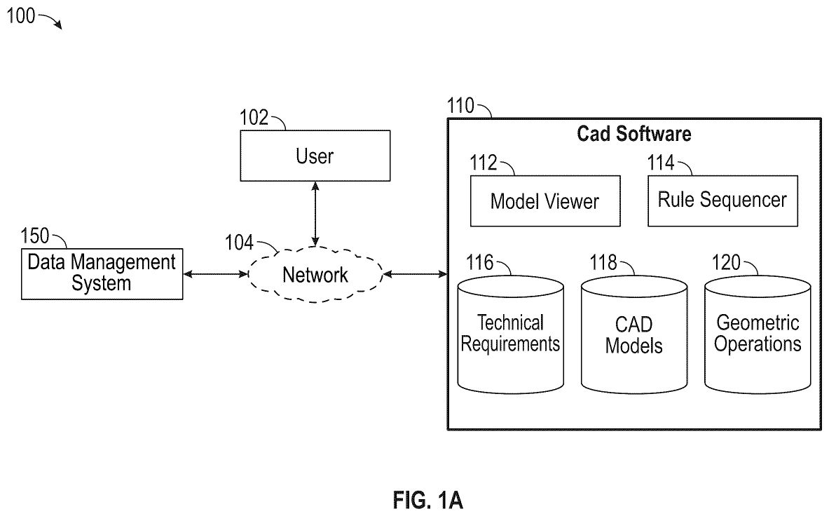

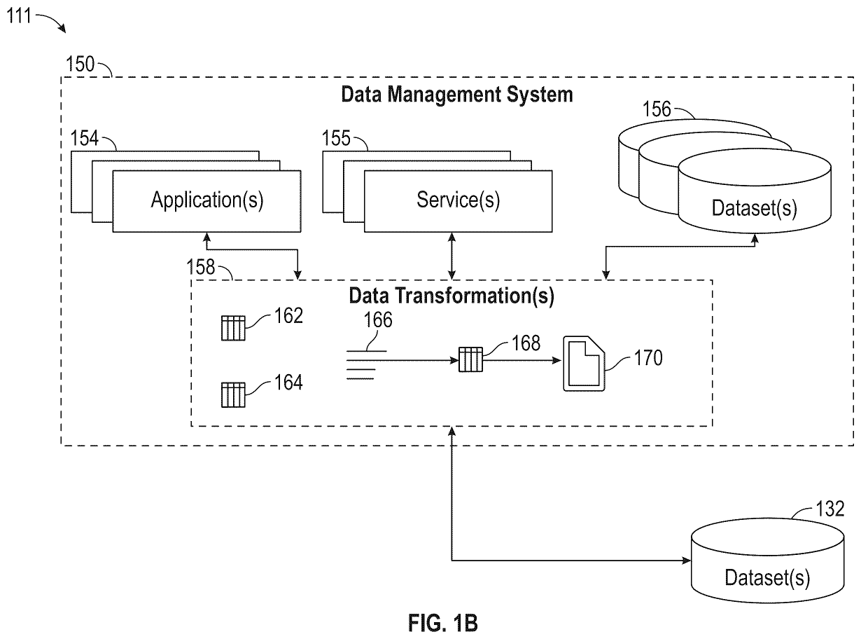

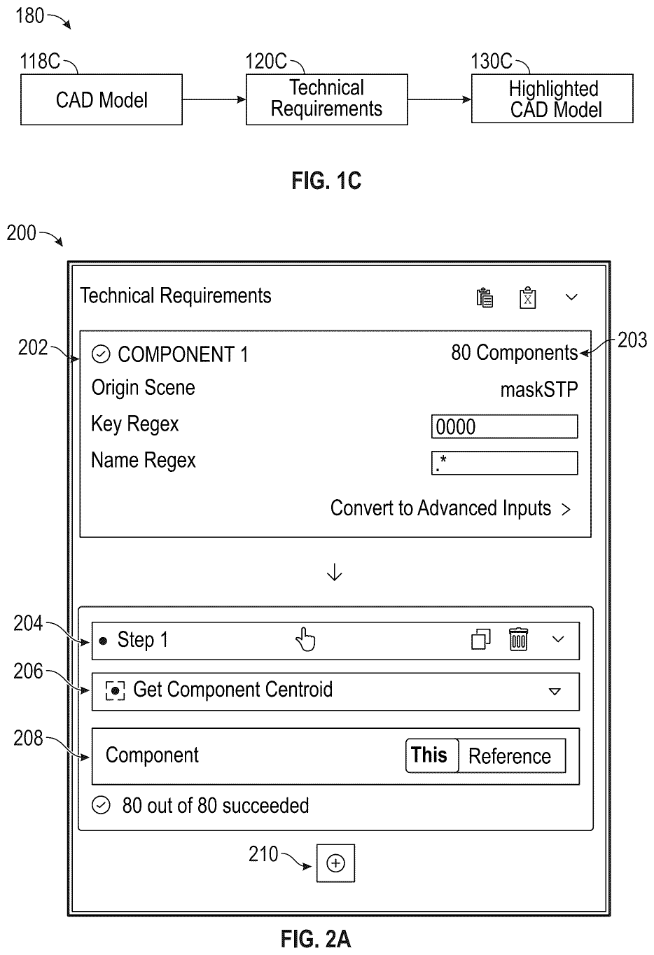

FIG. 1A illustrates a block diagram of an example CAD Model review computing environment 100. In the illustrated example, the computing environment 100 includes a user 102, a data management system 150, and CAD Analysis System 110. Moreover, the CAD Analysis System 110 comprises various modules, including a model viewer 112, a rule sequencer 114, a technical requirement database 116, a CAD model database 118, and a geometric operation database 120.

In the example of FIG. 1A, the user 102, data management system 150, and CAD Analysis System 110 are in communication via a network 104, which may include any combination of networks, such as one or more personal area network, local area network, wide area network, over-the-air broadcast network (e.g., for radio or television), cable network, satellite network, cellular telephone network, or combination thereof. As a further example, the network 104 may be a publicly accessible network of linked networks, possibly operated by various distinct parties, such as the Internet. In some cases, the network 104 may be a private or semi-private network, such as a corporate or university intranet. The network 104 may include one or more wireless networks, such as a Global System for Mobile Communications (GSM) network, a Code Division Multiple Access (CDMA) network, a Long-Term Evolution (LTE) network, or any other type of wireless network. The network 104 can use protocols and/or components for communicating via the Internet or any of the other aforementioned types of networks. For example, the protocols used by the network 104 may include Hypertext Transfer Protocol (HTTP), HTTP Secure (HTTPS), Message Queue Telemetry Transport (MQTT), Constrained Application Protocol (CoAP), and/or the like.

In some embodiments, modules of the illustrated components, such as the model viewer 112, the rule sequencer 114, the technical requirement database 116, the CAD model database 118, and the geometric operation database 120, may communicate via an internal bus and/or via the network 104.

The model viewer 112 may include a graphical user interface (GUI) that enables the user 102 to interactively view and manipulate an imported CAD model. For example, the user may import a CAD model of a piece of manufacturing equipment including various components. Manufacturing equipment, as used herein, may include any item that may be represented by a CAD model, such as, for example, an engine block, precision gear, plastic toy figurine, beverage bottle, bicycle frame, smartphone case, chair, glass bottle, furniture leg, PCB assembly, solar panel module, etc. Component information, such as a total count, dimensions, and other data may also be included in the CAD model import. This CAD model may originate from various sources, including third-party CAD software applications that export models in widely used formats such as STP (Standard for the Exchange of Product Model Data), STL (StereoLithography), or other industry-standard or proprietary file types. The GUI may provide functionality for visualizing the model in three dimensions, allowing the user to rotate, zoom, pan, and inspect individual components or assemblies. Additionally, the model viewer 112 may display updates to the CAD model as geometric computations are applied. For example, the CAD Model file (e.g., STP file) may be accessed by the CAD Analysis System 110, which can initially display a rendering of the original CAD model in a user interface of the users 102 device, such as a browser-based application or standalone application on the users 102 device. In this example, when geometric computations are applied to the CAD model, the model viewer 112 can update to display the geometric computations applied. For example, if a geometric computation to find the centroid of a strut of the CAD model is applied, the model viewer 112 can update the display of the CAD model to give an illustrative view of the location of the centroid for each strut (while ignoring the other components of the CAD model).

In some implementations, the CAD model displayed via the model viewer 112 can be filtered to show only specific components. For example, the model can be filtered to only show the struts within the model.

The model viewer 112 may update the CAD model display for each geometric computation applied to the CAD model via the rule sequencer 114. For example, the model viewer 112 may originally display the imported CAD model for a piece of manufacturing equipment. However, as the user applies geometric computations to the CAD model (via the rule sequencer 114), the model viewer 112 may continuously update displaying the results of each geometric computation.

The rule sequencer 114 may include a GUI that allows the user 102 to select geometric computations to apply to the CAD model. For example, the rule sequencer 114 may include a selection interface that allows the user 102 to select criteria to display the centroid for all struts in the CAD model. In this example, when the user 102 makes the selection, the model viewer 112 will automatically update the CAD model to display the selected changes.

The rule sequencer 114 may also access and apply a stored technical requirement (e.g., including a series of multiple geometric computations) to a CAD model, such as a newly generated (or updated) CAD model from a third-party CAD development software. The geometric computations may apply to any component of a CAD model (e.g., the struts), any combination of one or more components of a CAD model (e.g., the connection between two struts), and/or all of the components of the CAD model. The rule sequencer 114 is not limited by the type of components in the CAD model.

The rule sequencer 114 can be configured to apply a technical requirement that includes multiple geometric computations that are applied sequentially, and that build off of the previous computation. For example, the rule sequencer 114 may first apply a geometric computation that finds the centroid of a strut. The rule sequencer 114 may then be configured to apply a geometric computation that finds all struts in the CAD model that has a collision (with another component) at its centroid. The rule sequencer 114 can be configured to apply any one or more geometric computations as requested by the user 102. The rule sequencer 114 may thus be configured by the user 102 to review the CAD model for alignment with any one or more technical requirements by combining any one or more geometric computations in sequence.

Additionally, or alternatively, an existing technical requirement can be updated via the rule sequencer 114. For example, a technical requirement may change from finding every strut that has a collision at its centroid to finding every strut that has a collision at its endpoint. In this example, the user can modify the technical requirement (via the rule sequencer 114) to find the endpoints of the strut instead of the centroid. The technical requirement database 116 may store technical requirements that may be selected for application to CAD models. Additionally, the technical requirements database 116 may store the results of application of technical requirements, such as a list of components from a CAD model with potential issues based on application of a technical requirement. For example, a series of geometric computations may be applied to a CAD model to find all struts that are contacted at its centroid. The technical requirement database 116 can store component information such as a list of each strut, an indication of whether it failed (e.g., is contacted at its centroid) or passed (e.g., is not contacted at its centroid) and whether a review is required. In some implementations, some or all of the technical requirement's database is maintained by the data management system 150.

While in communication with the data management system 150, the CAD Analysis System 110 may access the technical requirement database 116. For example, following a series of geometric computations applied to the struts of the piece of manufacturing equipment, the list of struts and their associated data (e.g., the results of the series of geometric computations for each) can be sent to the data management system 150 for further review (as described in more detail herein).

In some implementations, if the reviewer selects not to review the component with a potential issue, the CAD Analysis System 110 may separate that component from the rest of the components in the technical requirement database 116. The technical requirement database 116 can thus be further sectioned into smaller groupings, such as new error information, previously reported errors, etc.

The technical requirement database 116 may be configured to only store component information for specific sections of the CAD model. For example, if the CAD model is of a piece of manufacturing equipment wherein the designer updated the base, the CAD Analysis System 110 may only store component information for components related to the base. In current systems, the CAD software may provide error information to the reviewer for all component errors, such as errors previously reported and ignored, errors for other portions of the CAD model (e.g., the “base” of the piece of manufacturing equipment) etc. By only storing component information for errors found in the specific portion of the CAD model that the designer updated, the technical requirement database 116 promotes efficiency in the system.

The CAD model database 118 may store the uploaded CAD models. The CAD model database 118 may store CAD models in any suitable format (e.g., .stp, .stl, etc.). Once the CAD model is stored in the CAD model database 118, the user may open the model at any point to apply a technical requirement (e.g., that includes a series of geometric computations). The CAD model database 118 can be configured to store the CAD model in its uploaded form, or in any updated form following a geometric computation.

The CAD model database 118 may be configured to store screenshots of the model from various views, angles, moments in the geometric computation sequence, etc. This stored information can be provided to an LLM. The LLM can provide component information such as component measurements, which components violate a technical requirement, how that component violates the technical requirement, etc. For example, a user can provide a narrative prompt to the LLM asking a high-level question about the CAD model such as whether all struts of the model are aligned with the xyz axis. The LLM can utilize the stored screenshots to quickly provide the user with a response, while avoiding the need to apply the series of geometric computations that may lead to determining whether the struts are aligned.

While in communication with the data management system 150, the CAD Analysis System 110 may access the CAD model database 118. For example, following a series of geometric computations that result in an updated CAD model that highlights every error associated with a specific technical requirement, the CAD Analysis System 110 may then upload the CAD model to the data management system 150 for further review (as described in more detail herein).

The geometric operation database 120 may include various geometric computations that are available for application to components of a CAD model. The geometric computations may include physical measurements of a component (e.g., find the center of the component, find the alignment of the component, etc.), as well as operations to filter or classify components (e.g., identifying all struts longer than a certain length). Additional types of geometric computations may include analyzing the shape and structure of components, such as working with meshes (e.g., Sphere_Mesh, Cylinder_Mesh, or other constant mesh) to detect collisions, calculate cross-sections (e.g., Mesh_Cross_Section_Polygon), or evaluate surface properties. Geometric computations may also involve working with polygons (e.g., Cross_Section_Polygon, Mesh_Face_Polygon, or other polygon) to define boundaries or regions, determining orientations and directions (e.g., Minimal_collision_orientation or Direction), and processing visual data (e.g., Image) for further analysis. Geometric computations may also include other operations, such as evaluating material properties like color, performing logical comparisons (e.g., Boolean), or handling numerical data types (e.g., Double, Integer) to support advanced calculations.

The geometric operation database 120 can include generic geometric computations such as “CreateSphere” or can include more complex geometric computations specifically created to solve a particular technical requirement. For example, in current systems, the reviewer would have to check every addition to the CAD model to make sure that a welding torch could access any necessary weld points at any point in time. This process would be difficult and time-consuming because the reviewer would check every component at every point in time during the assembly of the object. This system allows the user 102 to create a complex geometric computation (e.g., “FindFreeOrientation”) to solve this issue. For example, FindFreeOrientation can be configured to find an orientation of a welding torch that would allow the welding torch to access the weld at a certain point in time without being impeded by another component. This process can be repeated for each specific technical requirement that the user 102 may need to address.

Following a series of geometric computations, the component information stored in the technical requirement database 116 may be communicated to the data management system 150 for further review by the user. For example, a user may apply (via the rule sequencer 114) a series of geometric computations to the CAD model of the piece of manufacturing equipment to find which struts are contacted at their center point. The CAD Analysis System 110 will store (via the technical requirement database 116) information for each strut pertaining to the technical requirement (e.g., whether the strut is contacted, whether the contact needs reviewed, etc.) and can communicate that stored information to the data management system 150.

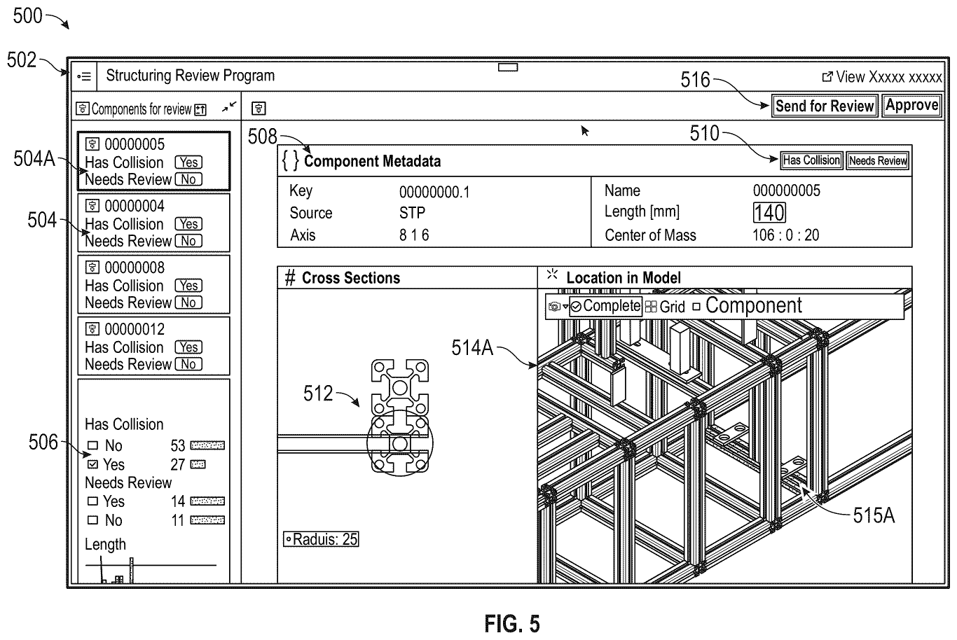

The data management system 150 may be configured to receive information from the CAD Analysis System 110 such as the CAD model (via the CAD model database 118), the component error information (via the technical requirement database 116), and/or the list of geometric computations (via the geometric operation database 120). The data management system 150 may allow the user 102 to review the component errors found in the CAD Analysis System 110 and respond appropriately. Additionally, or alternatively, the data management system 150 may include a database (e.g., database 132) that may store the technical requirements used to create the series of geometric computations. The data management system 150 is described in more detail herein with reference to FIG. 1B and FIG. 5.

### Example Technical Requirements Generation

As noted above, in some embodiments a user may select one or more geometric computations to be applied to CAD models and save those computations as a technical requirement. The technical requirements may then be accessed, e.g., automatically based on characteristics of the CAD model, user preferences, etc., and applied to CAD models to identify potential issues with the CAD model. In some embodiments, technical requirements may be generated and/or augmented through the use of artificial intelligence. For example, the user 102 may input requirements (e.g., a scan of an engineering requirements document or plain language description of technical requirements) that are provided to a large language model (LLM) with instructions on generation of properly formatted geometric computations. Thus, the LLM can receive the user requirements and output a list of technical requirements to be utilized by the user 102 in the rule sequencer 114.

### Example Data Management System

FIG. 1B further illustrates the example data management system 150 that may be in communication with the CAD Analysis System 110 of FIG. 1A, according to some embodiments of the present disclosure. In particular, the data management system 150 can be used with the computing environment 100 described above with respect to FIG. 1A. In the embodiments of FIG. 1B, a computing environment 111 can be similar to, overlap with, and/or be used in conjunction with the computing environment 100 of FIG. 1A. For example, the computing environment 111 can include a database 132, which may be similar to the technical requirement database 116, CAD model database 118, and/or geometric operation database 120 in the computing environment 100 of FIG. 1A. However, the computing environment 111 can also include a data management system 150.

The example data management system 150 includes one or more applications 154, one or more services 155, one or more initial datasets 156, and a data transformation process 158 (also referred to herein as a build process). The example data management system 150 can include a data pipeline system. The data management system 150 can transform data and record the data transformations. The one or more applications 154 can include applications that enable users to view datasets, interact with datasets, filter data sets, and/or configure dataset transformation processes or builds. The one or more services 155 can include services that can trigger the data transformation builds and API services for receiving and transmitting data. The one or more initial datasets 156 can be automatically retrieved from external sources and/or can be manually imported by a user. The one or more initial datasets 156 can be in many different formats such as a tabular data format (SQL, delimited, or a spreadsheet data format), a data log format (such as network logs), or time series data (such as sensor data).

The data management system 150, via the one or more services 155, can apply the data transformation process 158. An example data transformation process 158 is shown. The data management system 150 can receive one or more initial datasets 162, 164. The data management system 150 can apply a transformation to the dataset(s). For example, the data management system 150 can apply a first transformation 166 to the initial datasets 162, 164, which can include joining the initial datasets 162, 164 (such as or similar to a SQL JOIN), and/or a filtering of the initial datasets 162, 164. The output of the first transformation 166 can include a modified dataset 168. A second transformation of the modified dataset 168 can result in an output dataset 170, such as a report or a joined table in a tabular data format that can be stored in the database 132. Each of the steps in the example data transformation process 158 can be recorded by the data management system 150 and made available as a resource to the CAD Analysis System 110. For example, a resource can include a dataset and/or a dataset item, a transformation, or any other step in a data transformation process. As mentioned above, the data transformation process 158 can be triggered by the data management system 150, where example triggers can include nightly build processes, detected events, or manual triggers by a user. Additional aspects of data transformations and the data management system 150 are described in further detail below.

The techniques for recording and transforming data in the data management system 150 may include maintaining an immutable history of data recording and transformation actions such as uploading a new dataset version to the data management system 150 and transforming one dataset version to another dataset version. The immutable history is referred to herein as “the catalog.” The catalog may be stored in a database. Preferably, reads and writes from and to the catalog are performed in the context of ACID-compliant transactions supported by a database management system. For example, the catalog may be stored in a relational database managed by a relational database management system that supports atomic, consistent, isolated, and durable (ACID) transactions.

The catalog can include versioned immutable “datasets.” More specifically, a dataset may encompass an ordered set of conceptual dataset items. The dataset items may be ordered according to their version identifiers recorded in the catalog. Thus, a dataset item may correspond to a particular version of the dataset. A dataset item may represent a snapshot of the dataset at a particular version of the dataset. As a simple example, a version identifier of ‘1’ may be recorded in the catalog for an initial dataset item of a dataset. If data is later added to the dataset, a version identifier of ‘2’ may be recorded in the catalog for a second dataset item that conceptually includes the data of the initial dataset item and the added data. In this example, dataset item ‘2’ may represent the current dataset version and is ordered after dataset item ‘1’.

As well as being versioned, a dataset may be immutable. That is, when a new version of the dataset corresponding to a new dataset item is created for the dataset in the system, pre-existing dataset items of the dataset are not overwritten by the new dataset item. In this way, pre-existing dataset items (i.e., pre-existing versions of the dataset) are preserved when a new dataset item is added to the dataset (i.e., when a new version of the dataset is created). Note that supporting immutable datasets is not inconsistent with pruning or deleting dataset items corresponding to old dataset versions. For example, old dataset items may be deleted from the system to conserve data storage space.

A version of dataset may correspond to a successfully committed transaction against the dataset. In these embodiments, a sequence of successfully committed transactions against the dataset corresponds to a sequence of dataset versions of the dataset (i.e., a sequence of dataset items of the dataset).

A transaction against a dataset may add data to the dataset, edit existing data in the dataset, remove existing data from the dataset, or a combination of adding, editing, or removing data. A transaction against a dataset may create a new version of the dataset (i.e., a new dataset item of the dataset) without deleting, removing, or modifying pre-existing dataset items (i.e., without deleting, removing, or modifying pre-existing dataset versions). A successfully committed transaction may correspond to a set of one or more files that contain the data of the dataset item created by the successful transaction. The set of files may be stored in a file system.

In the catalog, a dataset item of a dataset may be identified by the name or identifier of the dataset and the dataset version corresponding to the dataset item. In a preferred embodiment, the dataset version corresponds an identifier assigned to the transaction that created the dataset version. The dataset item may be associated in the catalog with the set of files that contain the data of the dataset item. In a preferred embodiment, the catalog treats the set of files as opaque. That is, the catalog itself may store paths or other identifiers of the set of files but may not otherwise open, read, or write to the files.

In sum, the catalog may store information about datasets. The information may include information identifying different versions (i.e., different dataset items) of the datasets. In association with information identifying a particular version (i.e., a particular dataset item) of a dataset, there may be information identifying one or more files that contain the data of the particular dataset version (i.e., the particular dataset item).

The catalog may store information representing a non-linear history of a dataset. Specifically, the history of a dataset may have different dataset branches. Branching may be used to allow one set of changes to a dataset to be made independent and concurrently of another set of changes to the dataset. The catalog may store branch names in association with dataset version identifiers for identifying dataset items that belong to a particular dataset branch.

The catalog may provide dataset provenance at the transaction level of granularity. As an example, suppose a transformation is executed in the data management system 150 multiple times that reads data from dataset A, reads data from dataset B, transforms the data from dataset A and the data from dataset B in some way to produce dataset C. As mentioned, this transformation may be performed multiple times. Each transformation may be performed in the context of a transaction. For example, the transformation may be performed daily after datasets and B are updated daily in the context of transactions. The result being multiple versions of dataset A, multiple versions of dataset B, and multiple versions of dataset C as a result of multiple executions of the transformation. The catalog may contain sufficient information to trace the provenance of any version of dataset C to the versions of datasets A and B from which the version of dataset C is derived. In addition, the catalog may contain sufficient information the trace the provenance of those versions of datasets A and B to the earlier versions of datasets A and B from which those versions of datasets A and B were derived.

The provenance tracking ability is the result of recording in the catalog for a transaction that creates a new dataset version, the transaction or transactions that the given transaction depends on (e.g., is derived from). The information recorded in the catalog may include an identifier of each dependent transaction and a branch name of the dataset that the dependent transaction was committed against.

According to some embodiments, provenance tracking extends beyond transaction level granularity to column level granularity. For example, suppose a dataset version A is structured as a table of two columns and a dataset version B is structured as a table of five columns. Further assume, column three of dataset version B is computed from column one of dataset version A. In this case, the catalog may store information reflecting the dependency of column three of dataset version B on column one of dataset version A.

The catalog may also support the notion of permission transitivity. For example, suppose the catalog records information for two transactions executed against a dataset referred to in this example as “Transaction 1” and Transaction 2.” Further suppose a third transaction is performed against the dataset which is referred to in this example as “Transaction 3.” Transaction 3 may use data created by Transaction 1 and data created by Transaction 2 to create the dataset item of Transaction 3. After Transaction 3 is executed, it may be decided according to organizational policy that a particular user should not be allowed to access the data created by Transaction 2. In this case, as a result of the provenance tracking ability, and in particular because the catalog records the dependency of Transaction 3 on Transaction 2, if permission to access the data of Transaction 2 is revoked from the particular user, permission to access the data of Transaction 3 may be transitively revoked from the particular user.

The transitive effect of permission revocation (or permission grant) can apply to an arbitrary number of levels in the provenance tracking. For example, returning to the above example, permission may be transitively revoked for any transaction that depends directly or indirectly on the Transaction 3.

According to some embodiments, where provenance tracking in the catalog has column level granularity. Then permission transitivity may apply at the more fine-grained column level. In this case, permission may be revoked (or granted) on a particular column of a dataset and based on the column-level provenance tracking in the catalog, permission may be transitively revoked on all direct or indirect descendent columns of that column.

A build service can manage transformations which are executed in the system to transform data. The build service may leverage a directed acyclic graph data (DAG) structure to ensure that transformations are executed in proper dependency order. The graph can include a node representing an output dataset to be computed based on one or more input datasets each represented by a node in the graph with a directed edge between node(s) representing the input dataset(s) and the node representing the output dataset. The build service traverses the DAG in dataset dependency order so that the most upstream dependent datasets are computed first. The build service traverses the DAG from the most upstream dependent datasets toward the node representing the output dataset rebuilding datasets as necessary so that they are up-to-date. Finally, the target output dataset is built once all of the dependent datasets are up-to-date.

The data management system 150 can support branching for both data and code. Build branches allow the same transformation code to be executed on multiple branches. For example, transformation code on the master branch can be executed to produce a dataset on the master branch or on another branch (e.g., the develop branch). Build branches also allow transformation code on a branch to be executed to produce datasets on that branch. For example, transformation code on a development branch can be executed to produce a dataset that is available only on the development branch. Build branches provide isolation of re-computation of graph data across different users and across different execution schedules of a data pipeline. To support branching, the catalog may store information represents a graph of dependencies as opposed to a linear dependency sequence.

The data management system 150 may enable other data transformation systems to perform transformations. For example, suppose the system stores two “raw” datasets R1 and R2 that are both updated daily (e.g., with daily web log data for two web services). Each update creates a new version of the dataset and corresponds to a different transaction. The datasets are deemed raw in the sense that transformation code may not be executed by the data management system 150 to produce the datasets. Further suppose there is a transformation A that computes a join between datasets R1 and R2. The join may be performed in a data transformation system such a SQL database system, for example. More generally, the techniques described herein are agnostic to the particular data transformation engine that is used. The data to be transformed and the transformation code to transform the data can be provided to the engine based on information stored in the catalog including where to store the output data.

According to some embodiments, the build service supports a push build. In a push build, rebuilds of all datasets that depend on an upstream dataset or an upstream transformation that has been updated are automatically determined based on information in the catalog and rebuilt. In this case, the build service may accept a target dataset or a target transformation as an input parameter to a push build command. The build service than determines all downstream datasets that need to be rebuilt, if any.

As an example, if the build service receives a push build command with dataset R1 as the target, then the build service would determine all downstream datasets that are not up-to-date with respect to dataset R1 and rebuild them. For example, if dataset D1 is out-of-date with respect to dataset R1, then dataset D1 is rebuilt based on the current versions of datasets R1 and R2 and the current version of transformation A. If dataset D1 is rebuilt because it is out-of-date, then dataset D2 will be rebuilt based on the up-to-date version of dataset D1 and the current version of transformation B and so on until all downstream dataset of the target dataset are rebuilt. The build service may perform similar rebuilding if the target of the push build command is a transformation.

The build service may also support triggers. In this case, a push build may be considered a special case of a trigger. A trigger, generally, is a rebuild action that is performed by the build service that is triggered by the creation of a new version of a dataset or a new version of a transformation in the system.

A schema metadata service can store schema information about files that correspond to transactions reflected in the catalog. An identifier of a given file identified in the catalog may be passed to the schema metadata service and the schema metadata service may return schema information for the file. The schema information may encompass data schema related information such as whether the data in the file is structured as a table, the names of the columns of the table, the data types of the columns, user descriptions of the columns, etc.

The schema information can be accessible via the schema metadata service may versioned separately from the data itself in the catalog. This allows the schemas to be updated separately from datasets and those updates to be tracked separately. For example, suppose a comma separated file is uploaded to the system as particular dataset version. The catalog may store in association with the particular dataset version identifiers of one or more files in which the CSV data is stored. The catalog may also store in association with each of those one or more file identifiers, schema information describing the format and type of data stored in the corresponding file. The schema information for a file may be retrievable via the scheme metadata service given an identifier of the file as input. Note that this versioning scheme in the catalog allows new schema information for a file to be associated with the file and accessible via the schema metadata service. For example, suppose after storing initial schema information for a file in which the CSV data is stored, updated the schema information is stored that reflects a new or better understanding of the CSV data stored in the file. The updated schema information may be retrieved from the schema metadata service for the file without having to create a new version of the CSV data or the file in which the CSV data is stored.

When a transformation is executed, the build service may encapsulate the complexities of the separate versioning of datasets and schema information. For example, suppose transformation A described above in a previous example that accepts the dataset R1 and dataset R2 as input is the target of a build command issued to the build service. In response to this build command, the build service may determine from the catalog the file or files in which the data of the current versions of datasets R1 and R2 is stored. The build service may then access the schema metadata service to obtain the current versions of the schema information for the file or files. The build service may then provide all of identifiers or paths to the file or files and the obtained schema information to the data transformation engine to execute the transformation A. The underlying data transformation engine interprets the schema information and applies it to the data in the file or files when executing the transformation A.

### Example Applications of Technical Requirements

FIG. 1C illustrates an example data flow 180 showing application of technical requirements 120C, e.g., that may include multiple geometric calculations, to a CAD model for identifying potential issues with the components of a CAD model. In particular, the technical requirements 120C may be applied to the selected CAD model 118C by the CAD Analysis System 110 described above with respect to FIG. 1A. In the embodiment of FIG. 1C, technical requirements 120C may include multiple geometric operations (e.g., finding the centroid, finding the alignment of the component, detecting collisions etc.) that are automatically selected by the system 110 and/or selected by the user for application to a selected CAD model 118C.

As one example, the selected CAD model 118C may be a digital representation of a piece of industrial machinery comprised (in part) of multiple struts. The technical requirement 120C may be to determine whether each strut is contacted at its center point. This technical requirement 120C may be generated by the user 102 first selecting a geometric computation to find the centroid for each strut of the selected CAD model 118C. For example, the user 102 may select the “Get Component Centroid” geometric operation from the geometric operation database 120 that is configured to find the centroid of a component. The geometric operation may then be applied to the selected CAD model 118C to generate a reference centroid for the CAD model 130C.

This process can be repeated to apply multiple geometric operation to the selected CAD model 118C to ultimately result in the technical requirement 120C. In this example, the CAD model 130C can have a second geometric computation applied to it. For example, once the user 102 finds the centroid of each strut of the selected CAD model 118C, they may next select the “Get Major Axes of Component” geometric operation from the geometric operation database 120 that is configured to find the alignment of a component. The geometric operation may then be applied to the selected CAD model 118C to generate a new reference axis for the CAD model 130C that contains the alignment for each strut. The example process allows a user to sequentially apply more complex geometric computations to the selected CAD model 118C to identify potential issues in the CAD model 130C based on the technical requirement 120C.

The technical requirements 120C may be accessible by the user via an indexable search stream to be used again in future computations. For example, the technical requirements 120C may be reused the next time the user updates the CAD model. In such example, if a user updates the design for the base of the imported piece of manufacturing equipment CAD model, the system can automatically reapply the technical requirements 120C to determine if any struts of the piece of manufacturing equipment are now contacted at their center point following the update.

As another example, the user may import a CAD model for a different design, but the design may still have strut components that cannot be contacted at their center point. In such example, the system can store the series of geometric computations used to solve the technical requirements 120C so that the user can quickly access the technical requirements 120C to apply to the new CAD model design on demand.

### Example Geometric Computation Sequence to Review a Specific Technical Requirement

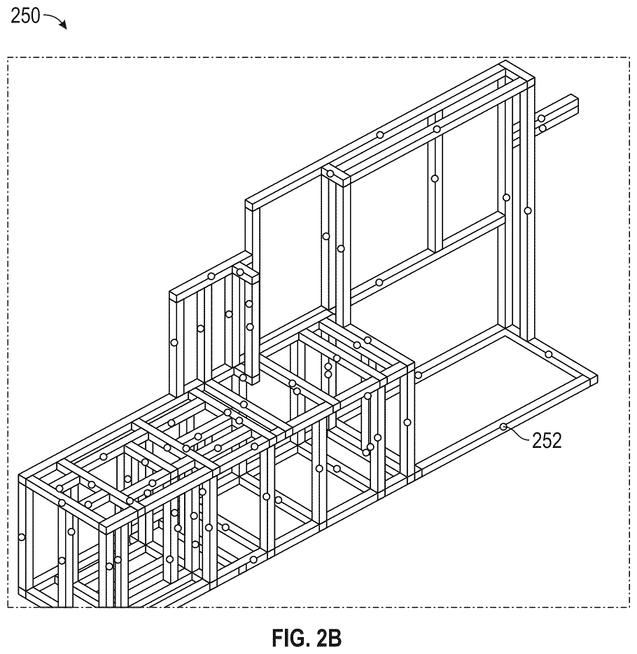

FIGS. 2-4 illustrate an example process of a user selecting geometric computations (e.g., based on engineering or business requirements for a particular product) to build technical requirements that may be applied to the CAD model in real-time (as the geometric computations are added) and/or automatically when the CAD model (or other CAD model with certain properties) is accessed by the CAD model viewer. In this example, an engineering requirement associated with a CAD model requires no strut component to be contacted at its center point. Therefore, the user can create a sequence of geometric computations as described in FIGS. 2-4 to automatically review the CAD model for any violations of this technical requirement.

FIG. 2A illustrates an example technical requirements interface 200 of a first geometric computation in a technical requirement for a CAD model. In this example, component information 202 is displayed for a selected CAD model (e.g., selected CAD model 118C), such as a result of a user selecting a certain component (e.g., “component 1”) on the CAD model or the user selecting a component type via a search, listing of components, or other manner. The component information 202 may include information such as the component type (e.g., a particular part type or number), a count 203 of the indicated component type in the selected CAD model, and/or other regex information that can be used to filter components of the CAD model for use in the subsequent geometric computations.

In the example of FIG. 2A, a first geometric computation step 204 outlines an initial geometric computation to apply to the identified components (e.g., Component 1) of the selected CAD model. The first geometric computation step 204 may include a first geometric computation 206 to be applied to a particular object identified in the computation subject field 208. In this example, “This” is selected to indicate that the geometric computation should be applied to each of the 80 components of type “Component 1”. The computation subject field 208 may include information necessary to identify and apply the selected geometric computation, including a reference to the component information 202 to apply the geometric computation (e.g., a component of the CAD model, a cross section of a polygon within the CAD model, etc.), dimensions of the created object (if the geometric computation is designed to create an object e.g., a cylinder). In this example, the computation subject field 208 to which the geometric computation “Get Component Centroid” is to be applied is “This” component, indicating that the geometric computation should be applied to each of the 80 components of type “Component 1”.

In the example of FIG. 2A, the “Get Component Centroid” first geometric computation 206 is selected for each component of type “Component 1”, causing the CAD model to display the centroid of each of the 80 matching components.

The step adder 210 allows the user to add an additional step to the sequential geometric computation. The added step may access the component at the point following the previous step. For example, if first geometric computation step 204 updates the CAD model to display the centroid for each component (e.g., strut), once the user selects the step adder 210, the added step may be applied to the strut with the centroid already displayed.

FIG. 2B illustrates an example display of an updated CAD model following the geometric computations performed in FIG. 2A. In this example, a CAD model 250 displays the latest geometric computation that was performed. As described in FIG. 2A, a geometric computation was applied to the CAD model to find the centroid of all struts in the CAD model (e.g., the 80 components of type “Component 1” in the CAD model). In this example, only the components that were selected in the technical requirements interface 200 are shown, to simplify visualization of those components. In some implementations, the other components of the model may be shown in different manners, such as very light gray that still allows easy visualization of the selected components. In the example of FIG. 2B, a centroid of each strut is shown with a dot 252, but in other embodiments the centroid may be shown in other manners. For example, a colored dot, line, or circle may be overlaid at each centroid of a component.

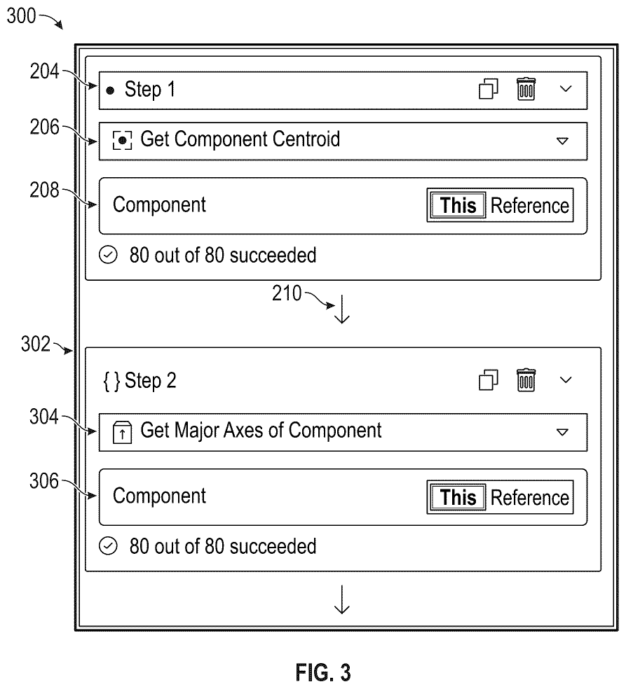

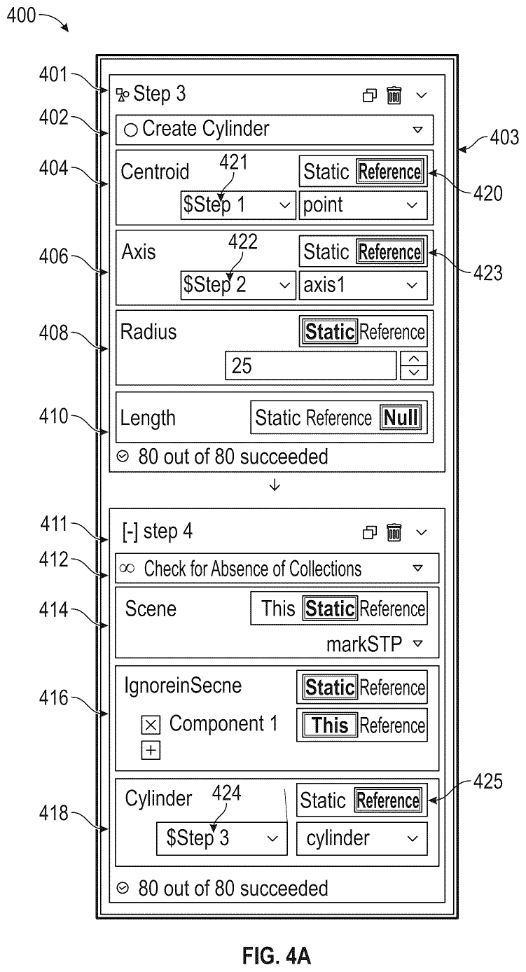

FIG. 3 illustrates an example GUI of technical requirement 300 that includes two sequential geometric computations. In this example, the first geometric computation step 204 as described in FIG. 2A is shown. Additionally, a second geometric computation step 302 was added (e.g., via the step adder 210). In the example of FIG. 3, the second geometric computation 304 can be a geometric computation such as “Get Major Axes of Component,” which would display the major axis (e.g., a primary alignment) of the same component identified in geometric computation step 1.

The second computation subject field 306 can be the same as computation subject field 208, allowing the first geometric computation 206 and second geometric computation 304 to sequentially build off each other to produce more intricate computations. For example, the second geometric computation 304 “Get Major Axes of Component” may not be applicable to the second computation subject field 306 without first finding the centroid of the component, as described in FIG. 2A. In such examples, the selected geometric computations must be applied sequentially to the component in order to determine the component's alignment.

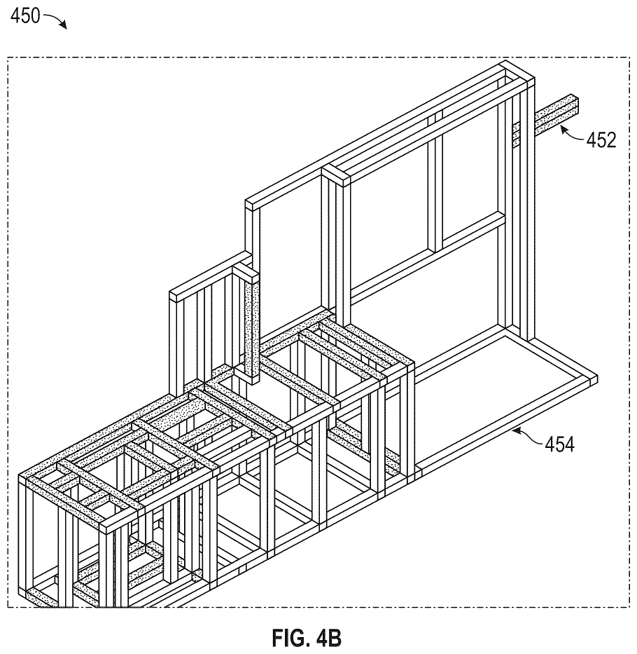

FIG. 4A illustrates an example GUI of technical requirement 400 that includes a third geometric computation step 401 and a fourth geometric computation step 411 applied to the sequence of FIG. 3. In this example, the technical requirement 400 includes a third geometric computation step 401 to create a cylinder and a fourth geometric computation step 411 to check for absence of collisions 412.

In the example FIG. 4A, a create cylinder geometric computation 402 is selected as “Create Cylinder,” and includes additional information associated with that computation, including centroid information 404, axis information 406, radius information 408, and length (of the created cylinder) information 410. In this example, some of this additional information for creation of a cylinder is calculated, and pre-filled, from previous steps of the technical requirement. For example, the component centroid information 404 indicates that the centroid should be pulled by reference 420 to the output 421 of “Step 1.” Similarly, the component axis information 406 indicates that the axis should be pulled by reference 423 to output 422 of “Step 2”. The component radius information 408 indicates a static radius of 25 units but could be automatically populated based on a reference to a previous step in the series of geometric computations or parameters of the component. For example, the radius information 408 could indicate that the cylinder radius is ten times the diameter of the component (e.g., 10 times the diameter of the strut, as stored in the CAD filed). The length information 410 can likewise be input statically by the user, automatically populated based on reference to output of a previous computation step or component property or set to automatic (or “Null” in this example). With the component length set to “Null” in this example, the cylinders (e.g., the 80 cylinders that are drawn around the 80 identified components) are automatically set to a negligible length relative to the scale of the CAD model.

As shown in the example FIG. 4A, the create cylinder geometric computation 402 requires more detailed component information than previous geometric computations. The system creates an efficient, less computationally intensive approach to applying geometric computations to CAD models by allowing the create cylinder geometric computation 402 to sequentially build off of the previous geometric computation steps by referencing those steps in the computation information 403.

Additionally, in the example FIG. 4A, a geometric computation is selected as “Check for Absence of Collisions,” and includes additional information associated with that computation, including scene information 414, ignore in scene information 416, and reference cylinder information 418. Similar to the geometric computation 402, some of this additional information for checking for an absence of a collision is calculated, and pre-filled, from previous steps of the technical requirement. For example, the scene information 414 indicates a static scene as the user uploaded maskSTP origin scene but could be automatically populated based on a reference to a previous step in the series of geometric computations, or could be set to “This” component, indicating that the scene should include only the components of type “Component 1.” Similarly, the reference cylinder information 418 indicates that the cylinder information should be pulled by reference 424 to the output 425 of “Step 3,” or could be a statis cylinder created by the user.

The ignore in scene information 416 can choose which components of the scene to apply the geometric computation to. In the example FIG. 4A, the ignore in scene information 416 creates a list of components that the check for absence of collisions 412 geometric computation should not be applied to. In this example, the “X” symbol indicates the selected components that should not be included in the list of ignored components, and the “+” symbol indicates the selected components that should be included in the list. In this example, the ignore in scene information is statically set to exclude each component of type “Component 1” in the CAD model from the list of components that will be ignored by the check for absence of collisions 412 geometric computation. In some embodiments, the ignore in scene information 416 could be automatically populated based on a reference to a previous step in the series of geometric computations or a parameter of the component. For example, the ignore in scene information 416 could indicate that the check for absence of collisions 412 geometric computation should ignore all components of the CAD model except for the cylinder created in Step 3.

Additionally, in the example FIG. 4A, the ignore in scene information 416 indicates that the check for absence of collisions 412 geometric computation should ignore all other components of the CAD model by not including any component information by the green “+” symbol. This allows the check for absence of collisions 412 geometric computation to only check for collisions with the specific component (e.g., components of type “Component 1”) that was selected to be ignored (as indicated by the “X” symbol). Further, the reference cylinder information 418 allows the user to only check for collisions specifically with the cylinder that was created at the centroid of the component.

The check for absence of collisions 412 geometric computation as shown in FIG. 4A can check the cylinder of each component 1 in the uploaded CAD model to see if there is another component “colliding” with that cylinder. If there is a collision, the system can highlight that component and mark it for review by the user. The sequence of geometric computations applied in FIGS. 2-4 allow the user to review components that violate the specified technical requirement above.

FIG. 4B illustrates an example display of a further updated CAD model 450 following the geometric computations performed in FIG. 4A. In this example, the check for absence of collisions 412 geometric computation is applied to each strut of the CAD model (e.g., the 80 components of type “Component 1” in the CAD model) to determine if there is a collision at its centroid. In this example, only the components that were selected in the technical requirements interface 200 are highlighted, while the remaining components of the CAD model are shown in very light gray, to allow for easy visualization of the selected component.

In the example FIG. 4B, an example colliding component 452 is highlighted red to represent that another component of the CAD model was determined (via the technical requirements described herein) to collide with the colliding component 452 at its centroid. Additionally, an example noncolliding component 454 may be highlighted green to represent that no other components of the CAD model collide with the noncolliding component 454 at its centroid.

### Example Gui Review Screen for a User

FIG. 5 illustrates an example GUI 500 of a user interface following application of a technical requirement. In this example, the GUI 500 displays to the user the results of the technical requirement for each component. For example, a particular review program 502 that checks each strut component of a CAD model for a collision at its center point (as described with reference to FIGS. 2-4 above) can be displayed for review in the user interface.

The user (such as, user 102) can select a review program 502 to generate a user interface detailing the results of a specific technical requirement (e.g., a sequence of geometric computations). The list of components for review 504 can initially include a list of each component in the CAD model that was reviewed in the technical requirement. The user may select a particular component 504A from the list of components for review 504 to display more detailed information about that component (such as, the component metadata 508, the component cross section 512, and the component GUI 514A).

As illustrated in the example FIG. 5A, the list of components for review 504 can be filtered based on the component filter 506. The component filter 506 provides the user with the option to filter the list of components for review 504 to show each component that has a collision (e.g., failed the technical requirements outlined in FIGS. 2-4) and/or is marked as either needs review or does not need review. For example, the system can determine if a component needs review based on whether it was previously presented to the user, if the component resides in a different area of the CAD model than the area that the designer had most recently updated the model, and/or any other factor that makes may cause the user to ignore the component collision.

The component metadata 508 may include metadata information such as the particular component 504A key number, scene, axis, name, length, center of mass, and/or any other metadata. The component metadata 508 further includes component failure information 510 indicating the results of the technical requirement for the particular component 504A for the user to quickly analyze the particular component 504A.

The component cross section 512 shows a cross-section view of a particular component 504A in the CAD model. The component cross section 512 displays detailed internal information about the particular component 504A. For example, as shown in FIG. 5A, the component cross section 512 of the strut shows that the component has four corner pieces that may be susceptible to breaking if there is another component colliding with the strut. In this example, the user would likely send this component for review (via the user selector 516). In another example, the component cross section 512 may reveal that the strut does not contain fragile pieces and would not be affected by a collision with another component. In such example, the user may approve (via the user selector 516) the particular component 504A irrespective of failing the technical requirement.

The component GUI 514A shows a representation 515A of the particular component 504A within the CAD model. In the example of FIG. 5, the component GUI 514A highlights the particular component 504A in red and shows its relative location in the CAD model, but in other embodiments the particular component 504A may be shown in other manners. For example, a line, circle, or pattern may be overlaid to emphasize the particular component 504A.

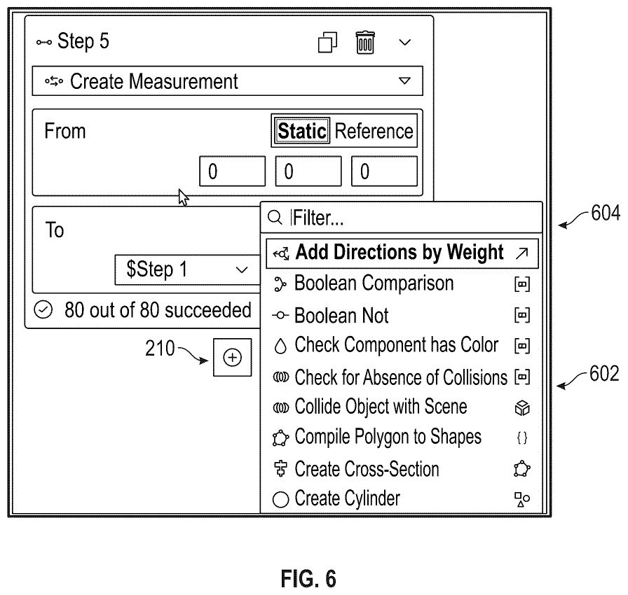

FIG. 6 illustrates an example list of geometric computations 602 that may be applied to a CAD model. The list of geometric computations 602 may be presented to the user when they select the step adder 210 to add an additional geometric computation to the technical requirement.

In the example FIG. 6, available geometric computations are displayed to the user in the list of geometric computations 602. However, this list is non-exhaustive. For example, the user can type in their desired geometric computation into the search bar 604 to utilize any geometric computation stored in the geometric operation database 120. Alternatively, new geometric computations can be added to the CAD Analysis System 110 to resolve unique challenges presented by a specific CAD model.

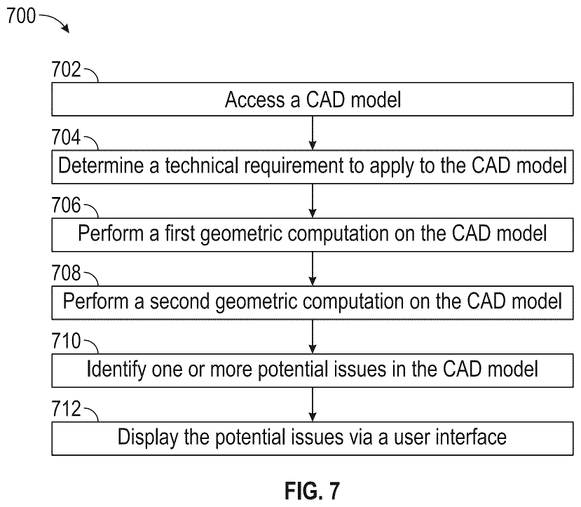

FIG. 7 is a flow chart illustrating an example process 700 for identifying and displaying potential issues in a CAD model. The process 700, or portions thereon, can be implemented by a computing device with a hardware processor. In some embodiments, the process 700, or portions thereon, can be performed by a computing device associated with the computing environment 100, such as the CAD Analysis System 110.

At block 702, in some embodiments, the system (e.g., the CAD Analysis System 110) can access a CAD model from a database (e.g., CAD model database 118). The CAD model can be displayed via a model viewer (e.g., model viewer 112). The model viewer 112 can be configured to display a 3D render of the CAD model which the user (e.g., user 102) can interact with to view different elements, angles, and/or other aspects of the CAD model. The model viewer 112 can be further configured to display various aspects of the CAD model, such as its various components. The CAD model can be in STP file format, or any other CAD supported format.

At block 704, in some embodiments, the system can determine a technical requirement to apply to the CAD model. The technical requirement can be stored in a technical requirement database (e.g., technical requirement database 116). The technical requirements can be uploaded by the user to be later applied to the CAD model. For example, an engineering requirement for a strut component of the CAD model that there is no collision with the strut at its center point can be reviewed by a specific technical requirement that contains a series of geometric computations that determine if a strut component has a collision at its center point.

As described herein, in some embodiments, a LLM can be used to generate engineering requirements to apply to the CAD model. For example, the user can supply an LLM with engineering documents, safety protocols, and/or other documentation specific to the CAD model. The LLM can output a list of engineering/safety requirements that may be applied to the CAD model. Additionally, the LLM can select previously created technical requirements to apply to the imported CAD model based on the LLM's analysis of the input documents.

At block 706, in some embodiments, the system can, via a rule sequencer (e.g., rule sequencer 114) perform a first geometric computation on the CAD model. A geometric computation may access component properties (such as dimensions, positions, or orientations, or other physical attributes) and apply geometric, arithmetic, and/or other logic operations to analyze, manipulate, or derive new information about the components or the overall CAD model. For example, a first geometric computation to assess the engineering requirement of a strut having no collisions at its center point may be to find the centroid (the center point) of the strut. The system would then be configured to apply this geometric computation to each strut of the CAD model to find each respective centroid. At block 708, in some embodiments, the system can, via the rule sequencer, perform a second geometric computation on the cad model. The second geometric computation may be based, at least in part, on the results of the first geometric computation. For example, once the centroid of each strut has been identified, the second geometric computation may be to find the alignment of each strut with respect to the component centroid.

As described herein, in some embodiments, additional geometric computations can be applied to the CAD model following the second geometric computation. For example, a third geometric computation, such as creating a cylinder around the component centroid, can be created. This process can be repeated indefinitely as needed to create a technical requirement to apply to the CAD model. The technical requirement can be stored in a technical requirement database (such as, technical requirement database 116) to be used repeatedly.

The second (or third, fourth, etc.) geometric computation can be a more intricate computation than the previous geometric computation. For example, finding the alignment of the strut component may not be possible without first finding the centroid. Further, creating a cylinder around the component centroid may not be possible without first finding the alignment of the strut.

As described herein, in some embodiments, each geometric computation can be created dynamically by the user for their specific engineering requirement. For example, if the geometric operation database 120 does not contain a geometric computation that can be used in a technical requirement for a specific engineering requirement, the user can create a new geometric computation specific to their needs.

Alternatively, the system may access and apply a stored technical requirement (e.g., including a series of geometric computations) to the CAD model. For example, following an update to a previously reviewed CAD model, the technical requirement for finding collisions at the center of the strut component stored in the technical requirement database would be accessed and applied to the updated CAD model.

At block 710, in some embodiments, the system can identify one or more potential issues in the CAD model. The potential issues in the CAD model can be based on the technical requirements as outlined in block 704. For example, the system can utilize the sequence of geometric computations performed in blocks 706 and 708 and apply a final geometric computation that is configured to identify any strut that has a collision at its center point.

At block 712, in some embodiments, the system can display the identified potential issues to the user via a user interface. The system can present the components identified in the technical requirement to the user in list format, allowing the user to select a component to review. The list of components may contain components with potential issues (according to the applied technical requirement), and/or may contain components that do not have any potential issues. Additionally, the list of components may be filtered to show all components, only components with potential issues, or only components without any potential issues. The list of components can be further filtered to show all components, only components that need reviewed, or only components that do not need reviewed.

The user interface can be configured to show detailed information for a selected component from the list of components. For example, the user interface may display to the user a cross section (e.g., component cross section 512) of the selected component, the component metadata (e.g., component metadata 508), and/or a GUI of the selected component highlighted within the CAD model (e.g., component GUI 514A). The user may utilize this information to make an informed decision as to whether the potential issue needs to be resolved be the designer or if the component is approved.

As described herein, in some embodiments, the system (via the model viewer 112) can visually highlight all struts in the CAD model based on the results of the final geometric computation. For example, the system can highlight red every strut with a collision and highlight green every strut that does not have a collision.

Although the example of FIG. 7 discusses an example process 700 of identifying and displaying potential issues with a CAD model, this is not intended to be limiting. Fewer, more, or different blocks could be included in the process 700. For example, although the process 700 describes applying technical requirements to the CAD model, it should be understood that in certain embodiments a user can alternatively send screenshots of the CAD model and engineering requirements to an LLM. The LLM can take the screenshots and technical requirements as input, and output whether any components of the CAD model fail an engineering requirement and/or need reviewed. For example, screenshots of a CAD model of a piece of manufacturing equipment and that equipment's respective struts can be input into an LLM, along with a requirement that struts should not be contacted at their center point. The LLM may return a list of struts that are contacted at their center point, based on the provided screenshots.

In some embodiments, the system can further comprise indexing search streams in the database management system to efficiently provide stored technical requirements that were previously used for the specific CAD model. For example, if the user imports an updated CAD model to the system, the user can efficiently find and apply the same technical requirements that were used in the previous iteration of the CAD model.

### Example Clauses

Examples of implementations of the present disclosure can be described in view of the following example clauses. The features recited in the below example implementations can be combined with additional features disclosed herein. Furthermore, additional inventive combinations of features are disclosed herein, which are not specifically recited in the below example implementations, and which do not include the same features as the specific implementations below. For sake of brevity, the below example implementations do not identify every inventive aspect of this disclosure. The below example implementations are not intended to identify key features or essential features of any subject matter described herein. Any of the example clauses below, or any features of the example clauses, can be combined with any one or more other example clauses, or features of the example clauses or other features of the present disclosure.

Clause 1. A computerized method, performed by a computing system having one or more hardware computer processors and one or more non-transitory computer readable storage device storing software instructions executable by the computing system to perform the computerized method comprising: accessing a CAD model; determining a technical requirement to be applied to the CAD model, the technical requirement including a plurality of geometric computations configured to identify potential design, manufacturing, compliance, functional, or optimization issues with the CAD model; performing a first geometric computation on the CAD model based; performing a second geometric computation on the CAD model, the second geometric computation based at least in part on results of the first geometric computation; identifying one or more potential issues in the CAD model based at least in part on results of the second or subsequent geometric computations; and displaying, via a user interface, the identified potential issues in the CAD model.

Clause 2. The method of clause 1, further comprising: automatically generating the technical requirement based on an engineering requirements document.

Clause 3. The method of clause 2, wherein the automatic generation of the technical requirement is performed by providing the engineering requirements document to a large language model (LLM) with examples of available geometric computations.

Clause 4. The computerized method of clause 1, wherein the second geometric computation is dynamically created based at least in part on an engineering requirements document.

Clause 5. The computerized method of clause 1, wherein the geometric computations of the technical requirement are configured to validate the CAD model for compliance with safety requirements.

Clause 6. The computerized method of clause 1, wherein the geometric computations of the technical requirement are configured to identify real-world issues associated with a product fabricated based on the CAD model.

Clause 7. The computerized method of clause 1, wherein the user interface includes controls usable to filter the identified potential issues.

Clause 8. The computerized method of clause 7, wherein a first filter is configured to update the user interface to display only potential issues specific to a user.

Clause 9. The computerized method of clause 7, wherein a second filter is configured to update the user interface to display of only potential issues associated with a particular portion of the CAD model.

Clause 10. The computerized method of clause 7, wherein a third filter is configured to suppress display of potential issues that have been previously indicated as resolved.

Clause 11. The computerized method of clause 1, wherein the first geometric computation comprises: capturing one or more screenshots of components of the CAD model; providing the one or more screenshots to a large language model (LLM); receiving structured information about the components of the CAD model from the LLM based at least in part on the one or more screenshots; and providing at least some of the structured information to the second geometric computation.

Clause 12. The computerized method of clause 1, further comprising: indexing search streams in a data management system; receiving user search queries via the data management system; determining responses to the user search queries based on the indexed search streams; and displaying, via the data management system, the determined responses to the user.

Clause 13. The computerized method of clause 1, wherein the CAD model is automatically highlighted to visually indicate components of the CAD model identified as having potential issues.

Clause 14. The computerized method of clause 1, further comprising dynamically updating the technical requirement based on modifications to the CAD model.

Clause 15. The computerized method of clause 1, wherein the user interface is configured to support real-time collaboration between multiple users, allowing simultaneous review and resolution of potential issues.

Clause 16. The computerized method of clause 1, further comprising integrating the CAD model with external systems, such as manufacturing execution systems (MES) or product lifecycle management (PLM) systems, to validate manufacturability.

Clause 17. The computerized method of clause 1, wherein the identified potential issues are categorized based on severity, type, or location within the CAD model.

Clause 18. The computerized method of clause 1, further comprising generating automated suggestions for resolving the identified potential issues.

Clause 19. The computerized method of clause 1, wherein a CAD model database tracks version history and allows users to compare potential issues across different versions of the CAD model.

Clause 20. The computerized method of clause 1, wherein geometric computations of the technical requirement are customizable by a user to address engineering, safety, design, or compliance requirements.

Clause 21. The computerized method of clause 1, further comprising applying the technical requirement to a batch of CAD models and generating a consolidated report of potential issues.

Clause 22. The computerized method of clause 1, wherein the geometric computations include predictive analysis to forecast potential issues based on historical data or trends.

Clause 23. The computerized method of clause 1, wherein the geometric computations of the technical requirement are dynamically adjusted based on user-defined parameters.

Clause 24. The computerized method of clause 1, wherein the geometric computations of the technical requirements are dynamically adjusted based on one or more of material properties, environmental conditions, or manufacturing constraints.

Clause 25. The computerized method of clause 1, further comprising storing the results of the applied technical requirements in a structured ontology to enable efficient querying, filtering, and analysis of the CAD model.

Clause 26. The computerized method of clause 1, wherein the technical requirement includes one or more geometric computations configured to detect component collisions during sequential assembly stages of the CAD model.

Clause 27. The computerized method of clause 1, further comprising generating a visual report summarizing the identified potential issues, including one or more of graphical representations, statistical data, and recommended corrective actions.

Clause 28. The computerized method of clause 1, further comprising enabling a user to define custom technical requirements by combining pre-existing geometric computations stored in a geometric operations database.

Clause 29. The computerized method of clause 1, further comprising automatically identifying and highlights components that are most likely to fail based on historical data, machine learning models, or statistical analysis.

Clause 30. The computerized method of clause 1, further comprising providing at least a portion of the CAD model and output of the technical requirement to a large language model (LLM) to provide narrative explanations of identified issues and their potential impact on a physical implementation.

Clause 31. The computerized method of clause 1, wherein the geometric computations simulate real-world conditions including one or more of thermal expansion, vibration, or load stress.

Clause 32. The computerized method of clause 1, further comprising automatically suppressing alerts for components that have been flagged as acceptable by the user in previous iterations of the CAD model.

Clause 33. The computerized method of clause 1, further comprising enabling a user to export results of the applied technical requirements in formats compatible with external analysis tools or regulatory compliance systems.

Clause 34. The computerized method of clause 1, further comprising hierarchical filtering of identified issues based on one or more of severity, location, or type.

Clause 35. The computerized method of clause 1, further comprising enabling a user to define geometric computations that incorporate temporal factors, such as changes in component properties over time or during assembly.

Clause 36. The computerized method of clause 1, further comprising enabling a user to configure alerts for specific types of potential issues, such as safety violations, manufacturing constraints, or functional errors.

Clause 37. The computerized method of clause 1, further comprising automatically generating a list of recommended geometric computations based on one or more of a type of CAD model or its intended application.

Clause 38. The computerized method of clause 1, further comprising: structuring results of the applied technical requirements based on an ontology that defines relationships between components, technical requirements, and geometric computations to enable semantic querying and advanced data analysis.

### Additional Implementation Details and Embodiments

Various embodiments of the present disclosure may be a system, a method, and/or a computer program product at any possible technical detail level of integration. The computer program product may include a computer readable storage medium (or mediums) having computer readable program instructions thereon for causing a processor to carry out aspects of the present disclosure.

For example, the functionality described herein may be performed as software instructions are executed by, and/or in response to software instructions being executed by, one or more hardware processors and/or any other suitable computing devices. The software instructions and/or other executable code may be read from a computer readable storage medium (or mediums).

The computer readable storage medium can be a tangible device that can retain and store data and/or instructions for use by an instruction execution device. The computer readable storage medium may be, for example, but is not limited to, an electronic storage device (including any volatile and/or non-volatile electronic storage devices), a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a solid state drive, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions (as also referred to herein as, for example, “code,” “instructions,” “module,” “application,” “software application,” and/or the like) for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Java, C++, or the like, and procedural programming languages, such as the “C” programming language or similar programming languages. Computer readable program instructions may be callable from other instructions or from itself, and/or may be invoked in response to detected events or interrupts. Computer readable program instructions configured for execution on computing devices may be provided on a computer readable storage medium, and/or as a digital download (and may be originally stored in a compressed or installable format that requires installation, decompression or decryption prior to execution) that may then be stored on a computer readable storage medium. Such computer readable program instructions may be stored, partially or fully, on a memory device (e.g., a computer readable storage medium) of the executing computing device, for execution by the computing device. The computer readable program instructions may execute entirely on a user's computer (e.g., the executing computing device), partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart(s) and/or block diagram(s) block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks. For example, the instructions may initially be carried on a magnetic disk or solid state drive of a remote computer. The remote computer may load the instructions and/or modules into its dynamic memory and send the instructions over a telephone, cable, or optical line using a modem. A modem local to a server computing system may receive the data on the telephone/cable/optical line and use a converter device including the appropriate circuitry to place the data on a bus. The bus may carry the data to a memory, from which a processor may retrieve and execute the instructions. The instructions received by the memory may optionally be stored on a storage device (e.g., a solid state drive) either before or after execution by the computer processor.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. In addition, certain blocks may be omitted in some implementations. The methods and processes described herein are also not limited to any particular sequence, and the blocks or states relating thereto can be performed in other sequences that are appropriate.

It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions. For example, any of the processes, methods, algorithms, elements, blocks, applications, or other functionality (or portions of functionality) described in the preceding sections may be embodied in, and/or fully or partially automated via, electronic hardware such application-specific processors (e.g., application-specific integrated circuits (ASICs)), programmable processors (e.g., field programmable gate arrays (FPGAs)), application-specific circuitry, and/or the like (any of which may also combine custom hard-wired logic, logic circuits, ASICs, FPGAs, etc. with custom programming/execution of software instructions to accomplish the techniques).

Any of the above-mentioned processors, and/or devices incorporating any of the above-mentioned processors, may be referred to herein as, for example, “computers,” “computer devices,” “computing devices,” “hardware computing devices,” “hardware processors,” “processing units,” and/or the like. Computing devices of the above-embodiments may generally (but not necessarily) be controlled and/or coordinated by operating system software, such as Mac OS, iOS, Android, Chrome OS, Windows OS (e.g., Windows XP, Windows Vista, Windows 7, Windows 8, Windows 10, Windows Server, etc.), Windows CE, Unix, Linux, SunOS, Solaris, Blackberry OS, VxWorks, or other suitable operating systems. In other embodiments, the computing devices may be controlled by a proprietary operating system. Conventional operating systems control and schedule computer processes for execution, perform memory management, provide file system, networking, I/O services, and provide a user interface functionality, such as a graphical user interface (“GUI”), among other things.

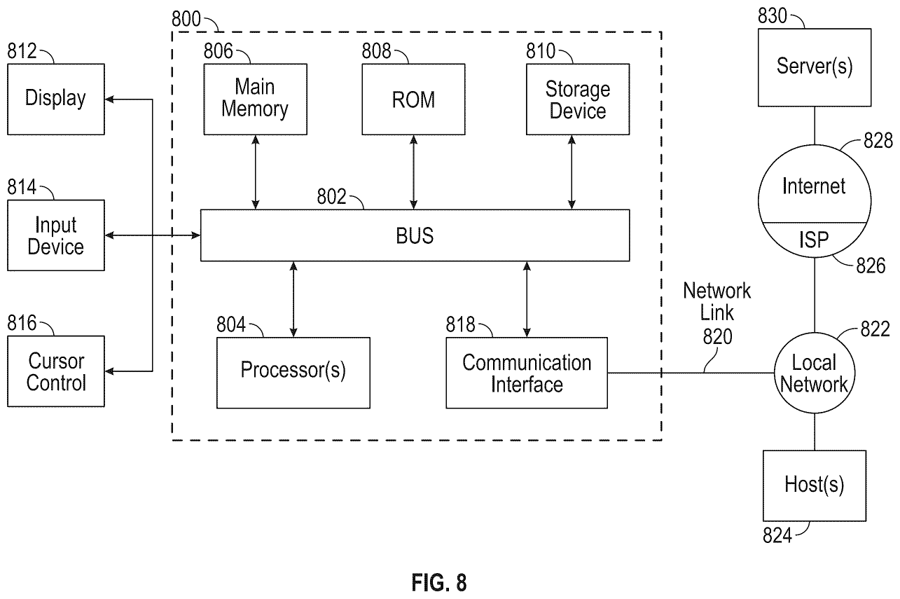

For example, FIG. 8 is a block diagram that illustrates a computer system 800 upon which various embodiments may be implemented. Computer system 800 includes a bus 802 or other communication mechanism for communicating information, and a hardware processor, or multiple processors, 804 coupled with bus 802 for processing information. Hardware processor(s) 804 may be, for example, one or more general purpose microprocessors.

Computer system 800 also includes a main memory 806, such as a random access memory (RAM), cache and/or other dynamic storage devices, coupled to bus 802 for storing information and instructions to be executed by processor 804. Main memory 806 also may be used for storing temporary variables or other intermediate information during execution of instructions to be executed by processor 804. Such instructions, when stored in storage media accessible to processor 804, render computer system 800 into a special-purpose machine that is customized to perform the operations specified in the instructions.

Computer system 800 further includes a read only memory (ROM) 808 or other static storage device coupled to bus 802 for storing static information and instructions for processor 804. A storage device 810, such as a magnetic disk, optical disk, or USB thumb drive (Flash drive), etc., is provided and coupled to bus 802 for storing information and instructions.

Computer system 800 may be coupled via bus 802 to a display 812, such as a cathode ray tube (CRT) or LCD display (or touch screen), for displaying information to a computer user. An input device 814, including alphanumeric and other keys, is coupled to bus 802 for communicating information and command selections to processor 804. Another type of user input device is cursor control 816, such as a mouse, a trackball, or cursor direction keys for communicating direction information and command selections to processor 804 and for controlling cursor movement on display 812. This input device typically has two degrees of freedom in two axes, a first axis (e.g., x) and a second axis (e.g., y), that allows the device to specify positions in a plane. In some embodiments, the same direction information and command selections as cursor control may be implemented via receiving touches on a touch screen without a cursor.

Computing system 800 may include a user interface module to implement a GUI that may be stored in a mass storage device as computer executable program instructions that are executed by the computing device(s). Computer system 800 may further, as described below, implement the techniques described herein using customized hard-wired logic, one or more ASICs or FPGAs, firmware and/or program logic which in combination with the computer system causes or programs computer system 800 to be a special-purpose machine. According to one embodiment, the techniques herein are performed by computer system 800 in response to processor(s) 804 executing one or more sequences of one or more computer readable program instructions contained in main memory 806. Such instructions may be read into main memory 806 from another storage medium, such as storage device 810. Execution of the sequences of instructions contained in main memory 806 causes processor(s) 804 to perform the process steps described herein. In alternative embodiments, hard-wired circuitry may be used in place of or in combination with software instructions.

Various forms of computer readable storage media may be involved in carrying one or more sequences of one or more computer readable program instructions to processor 804 for execution. For example, the instructions may initially be carried on a magnetic disk or solid state drive of a remote computer. The remote computer can load the instructions into its dynamic memory and send the instructions over a telephone line using a modem. A modem local to computer system 800 can receive the data on the telephone line and use an infra-red transmitter to convert the data to an infra-red signal. An infra-red detector can receive the data carried in the infra-red signal and appropriate circuitry can place the data on bus 802. Bus 802 carries the data to main memory 806, from which processor 804 retrieves and executes the instructions. The instructions received by main memory 806 may optionally be stored on storage device 810 either before or after execution by processor 804.

Computer system 800 also includes a communication interface 818 coupled to bus 802. Communication interface 818 provides a two-way data communication coupling to a network link 820 that is connected to a local network 822. For example, communication interface 818 may be an integrated services digital network (ISDN) card, cable modem, satellite modem, or a modem to provide a data communication connection to a corresponding type of telephone line. As another example, communication interface 818 may be a local area network (LAN) card to provide a data communication connection to a compatible LAN (or WAN component to communicated with a WAN). Wireless links may also be implemented. In any such implementation, communication interface 818 sends and receives electrical, electromagnetic or optical signals that carry digital data streams representing various types of information.

Network link 820 typically provides data communication through one or more networks to other data devices. For example, network link 820 may provide a connection through local network 822 to a host computer 824 or to data equipment operated by an Internet Service Provider (ISP) 826. ISP 826 in turn provides data communication services through the world wide packet data communication network now commonly referred to as the “Internet” 828. Local network 822 and Internet 828 both use electrical, electromagnetic or optical signals that carry digital data streams. The signals through the various networks and the signals on network link 820 and through communication interface 818, which carry the digital data to and from computer system 800, are example forms of transmission media.

Computer system 800 can send messages and receive data, including program code, through the network(s), network link 820 and communication interface 818. In the Internet example, a server 830 might transmit a requested code for an application program through Internet 828, ISP 826, local network 822 and communication interface 818.

The received code may be executed by processor 804 as it is received, and/or stored in storage device 810, or other non-volatile storage for later execution.

As described above, in various embodiments certain functionality may be accessible by a user through a web-based viewer (such as a web browser), or other suitable software program). In such implementations, the user interface may be generated by a server computing system and transmitted to a web browser of the user (e.g., running on the user's computing system). Alternatively, data (e.g., user interface data) necessary for generating the user interface may be provided by the server computing system to the browser, where the user interface may be generated (e.g., the user interface data may be executed by a browser accessing a web service and may be configured to render the user interfaces based on the user interface data). The user may then interact with the user interface through the web-browser. User interfaces of certain implementations may be accessible through one or more dedicated software applications. In certain embodiments, one or more of the computing devices and/or systems of the disclosure may include mobile computing devices, and user interfaces may be accessible through such mobile computing devices (for example, smartphones and/or tablets).

Many variations and modifications may be made to the above-described embodiments, the elements of which are to be understood as being among other acceptable examples. All such modifications and variations are intended to be included herein within the scope of this disclosure. The foregoing description details certain embodiments. It will be appreciated, however, that no matter how detailed the foregoing appears in text, the systems and methods can be practiced in many ways. As is also stated above, it should be noted that the use of particular terminology when describing certain features or aspects of the systems and methods should not be taken to imply that the terminology is being re-defined herein to be restricted to including any specific characteristics of the features or aspects of the systems and methods with which that terminology is associated.

Conditional language, such as, among others, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

The term “substantially” when used in conjunction with the term “real-time” forms a phrase that will be readily understood by a person of ordinary skill in the art. For example, it is readily understood that such language will include speeds in which no or little delay or waiting is discernible, or where such delay is sufficiently short so as not to be disruptive, irritating, or otherwise vexing to a user.

Conjunctive language such as the phrase “at least one of X, Y, and Z,” or “at least one of X, Y, or Z,” unless specifically stated otherwise, is to be understood with the context as used in general to convey that an item, term, etc. may be either X, Y, or Z, or a combination thereof. For example, the term “or” is used in its inclusive sense (and not in its exclusive sense) so that when used, for example, to connect a list of elements, the term “or” means one, some, or all of the elements in the list. Thus, such conjunctive language is not generally intended to imply that certain embodiments require at least one of X, at least one of Y, and at least one of Z to each be present.

The term “a” as used herein should be given an inclusive rather than exclusive interpretation. For example, unless specifically noted, the term “a” should not be understood to mean “exactly one” or “one and only one”; instead, the term “a” means “one or more” or “at least one,” whether used in the claims or elsewhere in the specification and regardless of uses of quantifiers such as “at least one,” “one or more,” or “a plurality” elsewhere in the claims or specification.

The term “comprising” as used herein should be given an inclusive rather than exclusive interpretation. For example, a general purpose computer comprising one or more processors should not be interpreted as excluding other computer components, and may possibly include such components as memory, input/output devices, and/or network interfaces, among others.

While the above detailed description has shown, described, and pointed out novel features as applied to various embodiments, it may be understood that various omissions, substitutions, and changes in the form and details of the devices or processes illustrated may be made without departing from the spirit of the disclosure. As may be recognized, certain embodiments of the inventions described herein may be embodied within a form that does not provide all of the features and benefits set forth herein, as some features may be used or practiced separately from others. The scope of certain inventions disclosed herein is indicated by the appended claims rather than by the foregoing description. All changes which come within the meaning and range of equivalency of the claims are to be embraced within their scope.

What is claimed is:

1. A computerized method, performed by a computing system having one or more hardware computer processors and one or more non-transitory computer readable storage device storing software instructions executable by the computing system to perform the computerized method comprising:
accessing a CAD model;
determining a technical requirement to be applied to the CAD model, the technical requirement including a plurality of geometric computations configured to identify potential design, manufacturing, compliance, functional, or optimization issues with the CAD model;
performing a first geometric computation on the CAD model based;
performing a second geometric computation on the CAD model, the second geometric computation based at least in part on results of the first geometric computation;
identifying one or more potential issues in the CAD model based at least in part on results of the second or subsequent geometric computations; and
displaying, via a user interface, the identified potential issues in the CAD model.

2. The method of claim 1, further comprising:
automatically generating the technical requirement based on an engineering requirements document.

3. The method of claim 2, wherein the automatic generation of the technical requirement is performed by providing the engineering requirements document to a large language model (LLM) with examples of available geometric computations.

4. The computerized method of claim 1, wherein the second geometric computation is dynamically created based at least in part on an engineering requirements document.

5. The computerized method of claim 1, wherein the geometric computations of the technical requirement are configured to validate the CAD model for compliance with safety requirements.

6. The computerized method of claim 1, wherein the geometric computations of the technical requirement are configured to identify real-world issues associated with a product fabricated based on the CAD model.

7. The computerized method of claim 1, wherein the user interface includes controls usable to filter the identified potential issues.

8. The computerized method of claim 7, wherein a first filter is configured to update the user interface to display only potential issues specific to a user.

9. The computerized method of claim 7, wherein a second filter is configured to update the user interface to display of only potential issues associated with a particular portion of the CAD model.

10. The computerized method of claim 7, wherein a third filter is configured to suppress display of potential issues that have been previously indicated as resolved.

11. The computerized method of claim 1, wherein the first geometric computation comprises:
capturing one or more screenshots of components of the CAD model;
providing the one or more screenshots to a large language model (LLM);
receiving structured information about the components of the CAD model from the LLM based at least in part on the one or more screenshots; and
providing at least some of the structured information to the second geometric computation.

12. The computerized method of claim 1, further comprising:
indexing search streams in a data management system;
receiving user search queries via the data management system;
determining responses to the user search queries based on the indexed search streams; and
displaying, via the data management system, the determined responses to the user.

13. The computerized method of claim 1, wherein the CAD model is automatically highlighted to visually indicate components of the CAD model identified as having potential issues.

14. The computerized method of claim 1, further comprising dynamically updating the technical requirement based on modifications to the CAD model.

15. The computerized method of claim 1, wherein the user interface is configured to support real-time collaboration between multiple users, allowing simultaneous review and resolution of potential issues.

16. The computerized method of claim 1, further comprising integrating the CAD model with external systems, such as manufacturing execution systems (MES) or product lifecycle management (PLM) systems, to validate manufacturability.

17. The computerized method of claim 1, wherein the identified potential issues are categorized based on severity, type, or location within the CAD model.

18. The computerized method of claim 1, further comprising generating automated suggestions for resolving the identified potential issues.

19. The computerized method of claim 1, wherein a CAD model database tracks version history and allows users to compare potential issues across different versions of the CAD model.

20. The computerized method of claim 1, wherein geometric computations of the technical requirement are customizable by a user to address engineering, safety, design, or compliance requirements.
